(19) United States
(12) Patent Application Publication
(10) Pub. No.: US 2003/0209803 A1
(43) Pub. Date: Nov. 13, 2003

(54) Semiconductor device and display panel module incorporating thereof

(76) Inventors: Takehiro Suzuki, Nara-shi (JP); Kenji Toyosawa, Ikoma-shi (JP)

Correspondence Address: HARNESS, DICKEY & PIERCE, P.L.C., P.O. BOX 8910, RESTON, VA, 20195, US

(21) Appl. No.: 10/434,166

(22) Filed: May 9, 2003

(30) Foreign Application Priority Data
May 10, 2002 (JP) 2002-136309

(51) Int. Cl. H01L 23/34

(52) U.S. Cl. 257/723

(57) ABSTRACT

The semiconductor device contains multiple semiconductor elements mounted on one carrier tape by COF. Here, the semiconductor elements are substantially rectangular and laid out so that the longitudinal directions thereof are aligned with, and lined up along, the longitudinal direction of the substantially rectangular carrier tape. The wires on the carrier tape interconnect adjacent semiconductor elements. This enables the size and cost of a display panel module to which the semiconductor device is mounted to be reduced, while avoiding characteristics abnormalities and a loss in signal transfer speed caused by added wiring distance of input signal wiring.

### FIELD OF THE INVENTION

The present invention relates to semiconductor devices and display panel modules in which the semiconductor devices as driving devices are mounted to liquid crystal and other display panels.

### BACKGROUND OF THE INVENTION

Recent years have seen shifts of display panels mounted to display panel modules, from cathode ray tubes to liquid crystal panels which are low in power consumption and compact in size and also have other various advantages. However, currently, the liquid crystal panel is priced about 10 times as much as the cathode ray tube. For further expansion of the liquid crystal panel market, cost cuts of the liquid crystal panel and peripherals are essential.

Conventionally, a semiconductor element constituting a liquid crystal driver for driving the liquid crystal panel is connected to the periphery of the liquid crystal panel after being packaged as a semiconductor device, using a carrier tape made up of an insulating film base material and a wiring layer formed thereon. The semiconductor element may be packaged using a carrier tape using COF (chip on FPC (flexible printed circuit)), TCP (tape carrier package), and other packaging methods.

In TCP, a hole (device hole) is formed through the film base material of the carrier tape to place a semiconductor element of which the connection terminals on the electrode surfaces are connected to inner leads which are wires extending into the device hole. In contras, in COF, the carrier tape has no device hole, and the inner leads connected to the semiconductor element is formed on the film base material.

COF is now attracting a great deal of interest in view of demands for reducing the frame width of the display panel module incorporating semiconductor devices in its periphery and hence for long and narrow semiconductor devices, because the packaging method readily allows for reducing the width of the semiconductor device. In comparison to TCP whereby the semiconductor element is connected to the inner leads extending over the device hole, COF whereby the inner leads are supported by the film base material is capable of readily producing semiconductor devices with small widths and in elongated shapes.

FIG. 8 shows an example of a liquid crystal panel module to which semiconductor devices are mounted. In FIG. 8, 51 represents a liquid crystal panel. COF semiconductor devices 54 packaged by multiple COF methods are connected (joined) to the periphery of the liquid crystal panel 51 by an anisotropic conductive film (ACF), etc. Each semiconductor device 54 includes a semiconductor element 55 chiefly constituting a liquid crystal driver (liquid crystal drive circuit).

In reference to FIGS. 9(a), 9(b), a manufacture step will be briefly described as an example of COF packaging. In FIGS. 9(a), 9(b), 101 represents a semiconductor element; 102, an input/output terminal electrode formed on a surface of the semiconductor element 101; 103, a gold bump electrode formed on the input/output terminal electrode 102; 104, insulative film base material; 105, a metal wiring pattern formed on a surface of a film base material 104; and 107, a bonding tool. 106 represents a carrier tape constituted by the film base material 103 and the metal wiring pattern 104.

First, as shown in FIG. 9(a), the semiconductor element 101 on which the gold bump electrode 103 is formed on the input/output terminal electrode 102 is positioned in relation to the inner lead 105 formed on the film base material 104, so that the bump electrode 103 sits at a predetermined position on the inner lead 105.

Here, the gold bump electrode 103 is about 10 μm to 18 μm in thickness. The film base material 104 constituting the carrier tape 106 is chiefly made of a plastic insulate material, such as polyimide resin or polyester. The main body of the metal wiring pattern 105 is made of copper (Cu) or another conductive substance, and its surface is plated with, for example, Sn or Au. The carrier tape 106 is shaped like a strip with carrier holes on the edges therethrough at predetermined intervals so that it can be moved along its length.

After the carrier tape 106 and the semiconductor element 101 are positioned, as shown in FIG. 9(b), the gold bump electrodes 103 are joined, using the bonding tool 107, to the metal wiring pattern 105 formed on the surface of the film base material 104 of the carrier tape 106 by thermocompression. The connecting method is typically called ILB (inner lead bonding).

After the ILB, as to the semiconductor device (not shown), the semiconductor element 101 is sealed with an epoxy resin, silicone resin, or other resin material. The resin seal is applied from a nozzle around the semiconductor element 101 and thermally cured by reflow, for example. Thereafter, the package portion of the semiconductor element 101 is punched out of the tape and mounted to a liquid crystal panel as an independent semiconductor device (semiconductor integrated circuit device).

As shown in FIG. 8, the semiconductor device 54 is mounted to the liquid crystal panel 51 on output outer leads 52 and input outer leads 53 which are external connection terminals of the semiconductor device 54. The output outer leads 52 are connected to the liquid crystal panel 51, and the input outer leads 53 are connected to a wired board 61.

The semiconductor devices 54 mounted to in the liquid crystal panel 51 need to share a common power source, input signals, etc., and therefore exchange signals and obtain operational power through the circuit board 61.

Incidentally, relatively compact liquid crystal panel modules, for example, those which are used in mobile telephones, are inexpensive also due to their driving methods, etc., and each liquid crystal panel includes one liquid crystal driver (semiconductor element) mounted thereto. However, a large-scale AV (audio visual) liquid crystal panel, such as those in liquid crystal television sets, needs multiple liquid crystal drivers (semiconductor elements) and is still expensive. The growth in size of the liquid crystal panel tends to be being accelerated.

With the growth in size of the liquid crystal panel, the number of semiconductor devices 54 shown in FIG. 8 used increases. Proportionately, the wired board 61 joining the semiconductor devices 54 together at an input terminal section grows into an extremely large size. The wired board 61 grows not only in size, but also in weight, applying excessive stress to a portion joined to the semiconductor devices 54 and possibly developing line breaks and other defects. The provision of the wired board 61 adds to the size of the liquid crystal panel module, which runs counter to the recent trend for more compact devices.

In addition, the carrier tape, which is a basic component for TCP, COF, etc., is very expensive. The more semiconductor elements are packaged, the more costly the product. No further cost cuts are possible without reducing the cost of the basic component.

Inventions directed to semiconductor devices have been made so far for the purpose of reducing the cost and size of the liquid crystal panel module.

For example, Published Unexamined Patent Applications 5-297394 (Tokukaihei 5-297394/1993) and 6-258651 (Tokukaihei 6-258651/1994) disclose arrangements in which less boards are used to link the semiconductor devices, i.e., less wired boards 61 in the case of FIG. 8. Published Unexamined Patent Application 11-150227 (Tokukaihei 11-150227/1999) discloses a technique to package multiple semiconductor elements on a single TCP.

Now, major aspects of the techniques disclosed in these documents will be described.

(i) Published Unexamined Patent Application 5-297394 (published on Nov. 12, 1993)

FIG. 10(a) shows a plan view of a liquid crystal panel module of the Published Unexamined Patent Application, and FIG. 10(b) shows an enlarged view of the two semiconductor devices mounted to the liquid crystal panel module, adjacent to the liquid crystal panel.

In FIG. 10(a), in the liquid crystal panel module, multiple TCP-packaged semiconductor devices 200 are mounted to the liquid crystal panel 201 on the top and bottom sides along the periphery. Each semiconductor device 200 contains a substantially rectangular packaged semiconductor chip (semiconductor element) 202 constituting a liquid crystal driver, etc. The semiconductor chip 202 is provided with output outer leads 203 and input outer leads 204. The semiconductor chip 202 is sealed with resin.

A slit 205 is provided to a part of the film base material where the input outer leads 204 are provided as shown in detail in FIG. 10(b). Each semiconductor device 200 is connected with those that are adjacent thereto through the outer leads 204 extending along the length of the semiconductor element 202.

Under these conditions, the semiconductor devices 200 are connected to the liquid crystal panel 201 in a conventional manner, by the output outer leads 203. Adjacent semiconductor devices 200 are connected by stacking the slits 205 and joining the outer leads 204 of the two devices together.

Providing the outer leads 204 on both ends of the semiconductor element 202 of each semiconductor device 200 and joining the adjacent semiconductor devices 200 by the outer leads 204 in this manner eliminates the need for a wired board connecting the semiconductor devices, or the wired board 61 in FIG. 8, and allows for reduction in size and cost of the liquid crystal panel module.

(ii) Published Unexamined Patent Application 6-258651 (published on Sep. 16, 1994) FIG. 11(a) shows a plan view of a liquid crystal display of the Published Unexamined Patent Application, and FIG. 11(b) shows a plan view of a liquid crystal driver tape carrier package (semiconductor device) mounted to the liquid crystal panel in the liquid crystal display.

In FIG. 11(a), along the periphery of the liquid crystal panel 309 are there provided H top-side TCPs 305, V-side TCPs 306, H bottom-side TCPs 307, and a signal input terminal 308. Each TCP 301, which will fabricated into these H top-side TCPs 305, V-side TCPs 306, and H bottom-side TCPs 307, contains a packaged liquid crystal driver 302 as shown in FIG. 11(b) and is provided with input terminals 303 and output terminals 304.

The signal input via the signal input terminal 308 is passed through the wiring on the liquid crystal panel 309 and transmitted to the H top-side TCPs 305, H bottom-side TCPs 307, and V-side TCPs 306. The liquid crystal driver 302 supplies a liquid crystal drive signal to the liquid crystal panel 309 in accordance with the input signal. Here, the input terminals of the adjacent TCPs transmit the input signal through the connection with the wiring on the liquid crystal panel 309.

Therefore, the arrangement of the Published Unexamined Patent Application also eliminates the need for a wired board connecting the semiconductor devices, or the wired board 61 in FIG. 8, and allows for reduction in size and cost of the liquid crystal panel module.

(iii) Published Unexamined Patent Application 11-150227 (published on Jun. 2, 1999)

FIG. 12(a) shows a plan view of a liquid crystal driver (semiconductor device) of the Published Unexamined Patent Application, and FIG. 12(b) shows a plan view of a liquid crystal driver chip (semiconductor element) made from a combined body of two adjacent chips mounted to the liquid crystal driver.

In FIGS. 12(a) and 12(b), 410, 411 are liquid crystal driver chips each having 80 outputs (80 output terminals). The input terminals 412, 413 of the two liquid crystal driver chips are joined together using inner lead wires 415 of a carrier tape 414 and enclosed in a single tape carrier package. Mounting two liquid crystal driver chips each having 80 outputs to a single carrier tape provides 160 outputs to the liquid crystal driver.

Mounting multiple semiconductor elements to a single carrier tape in this manner reduces the number of necessary carrier tapes, and allows for reduction in cost and size of the liquid crystal panel module.

However, the conventional techniques disclosed in the prior art documents (i)-(iii) have following problems.

In the arrangement (i), less wired boards 61 are used as shown in FIG. 8, successfully avoiding defects caused by line breaks and an increase in size of the liquid crystal panel module. However, the arrangement requires a connecting step for the slits 505. The technique does not reduce the quantities and counts of basic components (carrier tapes) used in the semiconductor device 200, offering no improvement over the current situation. Basic components are required which are as many as the semiconductor chip 202, allowing no cost reduction by the use of less basic components.

In the arrangement (ii), less wired boards 61 are used as shown in FIG. 8, successfully avoiding defects caused by line breaks and an increase in size of the liquid crystal panel module. However, similarly to the arrangement (i), the technique does not reduce the counts of the basic components (carrier tapes) used in the TCPs 305-307, offering no improvement over the current situation. No cost reduction is achieved.

The method whereby, as in (i), (ii), multiple semiconductor devices 200 or TCPs 305-307 are mounted to the periphery of the liquid crystal panel 201, 309 shows poor versatility when the liquid crystal panel 201, 309 is resized while retaining the current pixel count. This is because the pitch between the outer leads 203 or the output terminals 304 of the liquid crystal panel 201, 309 and the semiconductor device 200 or the TCPs 305-307 must be changed.

Further, in the arrangements (i), (ii), an input signal is fed to a part of the liquid crystal panel 201, 309 from which the signal is fed to all the semiconductor devices 200 or TCPs 305-307 via the semiconductor devices 200 or TCPs 305-307.

That is, in the arrangement (i), as shown in FIG. 10(a), a signal is fed to the input outer leads 204 of the semiconductor device 200 located on the far right or far left, and transferred through the semiconductor chip 202 in the adjacent semiconductor device 200. The transferred signal is passed further through the semiconductor chip 202 in the next semiconductor device 200 and then transferred on to the subsequent semiconductor device 200. The same action is repeated until the signal is transferred to all the connected semiconductor devices 200.

Meanwhile, in the arrangement (ii), as shown in FIG. 11(a), a signal is fed to a signal input terminal 308 located at a corner of the liquid crystal panel 309. First, the signal is transferred to those TCPs 305-307 that are located nearest to the signal input terminal 308 of all the TCPs 305-307 each provided in plurality, and sequentially transferred to the adjacent TCPs 305-307 through the wiring on the liquid crystal panel 309, so that the signal is transferred to all the TCPs 305-307 mounted along the periphery of the liquid crystal panel 309.

Therefore, in these arrangements of (i), (ii), very long wiring is required to transfer the input signal (including power supply) from the first semiconductor device 200 or TCP 305-307 to the last semiconductor device 200 or TCP 305-307.

Long wiring is a cause for unwanted voltage drop; the signal input may show different characteristics in the first semiconductor device 200 or TCP 305-307 and in the last semiconductor device 200 or TCP 305-307. The voltage drop is not so serious at current levels as it poses any problem; however, it can be a cause for display abnormalities in the future due to increasingly high resolution and brightness of the liquid crystal panel and other like reasons. Long wiring requires a higher speed operation of the input signal and is fatal to the improvement of the operation speed of the input signal.

In contrast, in the arrangement (iii), less carrier tapes are used than driver chips (semiconductor elements). This contributes to cost cut and panel size reduction. In addition, the pitch between the outer leads of the liquid crystal driver does not need to be changed even if the liquid crystal panel is resized while retaining the old pixel count. The arrangement (iii) therefore offers superior versatility. Packaging multiple semiconductor elements in one semiconductor device makes the input signal wiring that should be used commonly by the semiconductor elements shorter than in the arrangements (i), (ii).

However, the arrangement (iii), employing TCP, mounts the two liquid crystal driver chips in one device hole through the basic component and joins the two chips through the inner lead wires 415. The wires connecting chips are therefore run in a square “U” shape, adding to the length of the wires.

As previously mentioned in relation to the problems of the arrangement (i), (ii), wires with added lengths can be a cause for various inconveniences: namely, voltage drop and other phenomena, and hence abnormal characteristics (display abnormalities), as well as needs for higher speed operation of the input signal.

### SUMMARY OF THE INVENTION

The present invention, in view of the problems, has an objective to provide a semiconductor device and a display panel module which are capable of reducing the size and cost of the display panel module, while reducing characteristics abnormalities caused by added length of input signal wiring and avoiding a loss in signal transfer speed.

A semiconductor device in accordance with the present invention, to achieve the objective, includes multiple semiconductor elements packaged using one carrier tape including an insulating film base material and a wiring layer formed thereon,

the semiconductor elements being substantially rectangular and laid out so that longitudinal directions thereof are aligned with, and lined up along, a longitudinal direction of the substantially rectangular carrier tape,

the film base material existing between adjacent semiconductor elements, and

the wiring layer formed on the film base material interconnecting the adjacent semiconductor elements.

First, this mounts multiple semiconductor elements together on a single carrier tape. The following functions are enabled. The number of expensive carrier tapes is reduced, and so is the cost. A single packaging step is capable of connecting the semiconductor device to the display panel; the number of steps is reduced, and so is the cost. Besides, unlike those cases when semiconductor devices in which semiconductor elements are individually packaged are mounted, there is no need for a wired board linking the semiconductor devices. The device therefore enables cost reduction and allows for downsizing of the display panel module. Besides, the length of the input signal wiring can be reduced, in comparison to those cases when semiconductor devices in which semiconductor elements are individually packaged are mounted. This makes it possible to avoid occurrence of, for example, characteristics abnormalities (display abnormalities) caused by a voltage drop or like phenomena which is a defect caused by added length of the input signal wiring and greater need for high speed operation of the input signal. Further, the pitch between the outer leads of the semiconductor device does not need to be changed even if the display panel is resized while retaining the original pixel count of the display panel. Good versatility is obtained.

Next, with the arrangement, the semiconductor elements are substantially rectangular and laid out so that the longitudinal directions thereof are aligned with, and lined up along, the longitudinal direction of the substantially rectangular carrier tape. This enables the semiconductor device to have a long and narrow shape. By making the semiconductor device in a long and narrow shape, when a display panel module is arranged by mounting a semiconductor device to the periphery of a display panel, those situations can be effectively avoided in which the frame of the module on the side to which the semiconductor device is mounted becomes too wide.

In addition, with the arrangement, the film base material exists between the adjacent semiconductor elements, and the wiring layer formed on the film base material interconnects the adjacent semiconductor elements. Therefore, the input signal wiring distance can be made short (the elements can be interconnected through straight paths), in comparison to the arrangement (iii) of the aforementioned conventional technique, that is, the arrangement in which the wires are drawn outside the device hole and run in a square “U” shape. Defects are more effectively avoided which are caused by added length of the input signal wiring.

As a result, a semiconductor device can be provided which enables reduction in size and cost of the liquid crystal panel module, while reducing characteristics abnormalities which occur due to added wiring distance for input signals and avoiding losses in signal transfer speed.

Besides, the semiconductor device in accordance with the present invention is preferably arranged so as to be of a COF type where the carrier tape does not have a hole in which the semiconductor elements are mounted.

A display panel module in accordance with the present invention, to achieve the objective, includes a semiconductor device mounted to a periphery of a display panel as a drive circuit for driving the display panel, the semiconductor device having multiple semiconductor elements packaged using one carrier tape including an insulating film base material and a wiring layer formed thereon,

the semiconductor elements in the semiconductor device being substantially rectangular and laid out so that longitudinal directions thereof are aligned with, and lined up along, a longitudinal direction of the substantially rectangular carrier tape,

the film base material existing between adjacent semiconductor elements, and

the wiring layer formed on the film base material interconnecting the adjacent semiconductor elements.

As mentioned earlier, the semiconductor device in accordance with the present invention is a semiconductor device which enables reduction in size and cost of the liquid crystal panel module, while reducing characteristics abnormalities which occur due to added wiring distance for input signals and avoiding losses in signal transfer speed.

Therefore, the display panel module in accordance with the present invention in which such a semiconductor device is mounted enables reduction in size and cost, while reducing characteristics abnormalities which occur due to added wiring distance for input signals and avoiding losses in signal transfer speed.

For a fuller understanding of the nature and advantages of the invention, reference should be made to the ensuing detailed description taken in conjunction with the accompanying drawings.

### BRIEF DESCRIPTION OF THE DRAWINGS

FIG. 1 is a plan view schematically showing an arrangement of a liquid crystal panel module of an embodiment in accordance with the present invention.

FIG. 2 is a plan view showing an arrangement of a semiconductor device in the liquid crystal panel module.

FIG. 3 is a wiring diagram illustrating signal transfer paths for an input signal in the semiconductor device.

FIG. 4 is a drawing illustrating defects in a signal transfer path for an input signal in the semiconductor device.

FIG. 5 is a drawing illustrating other defects in a signal transfer path for an input signal in the semiconductor device.

FIG. 6 is a schematic showing on-board wiring formed on a glass board of a liquid crystal panel in the liquid crystal panel module.

FIG. 7 is a schematic showing, as another example, on-board wiring formed on a glass board of a liquid crystal panel in the liquid crystal panel module.

FIG. 8 is a plan view showing a conventional arrangement of a display panel module.

FIG. 9(a) and FIG. 9(b) are both a cross-sectional view illustrating ILB connection.

FIG. 10(a) is a plan view illustrating another conventional arrangement of a display panel module, and FIG. 10(b) is a plan view showing an adjacent semiconductor device in the display panel module.

FIG. 11(a) is a plan view illustrating a further conventional arrangement of a display panel module, and FIG. 11(b) is a plan view showing a semiconductor device mounted to the display panel module.

FIG. 12(a) is a plan view showing a conventional semiconductor device, and FIG. 12(b) is a plan view showing a semiconductor chip mounted to the semiconductor device.

### DESCRIPTION OF THE EMBODIMENTS

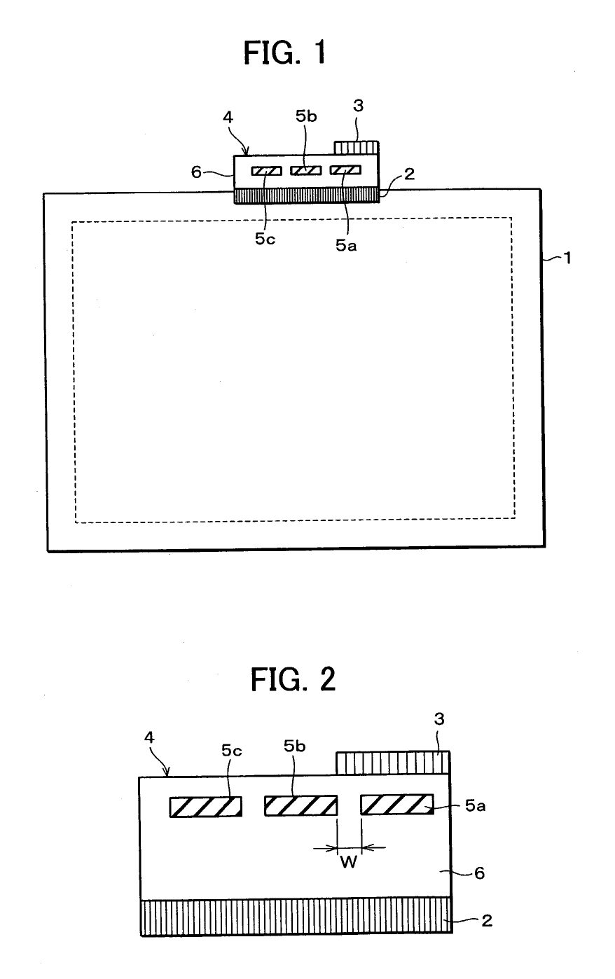

The following will describe an embodiment in accordance with the present invention in reference to FIGS. 1 to 7.

FIG. 1 is a plan view illustrating a structure of a liquid crystal panel module as a display panel module of the present embodiment. In FIG. 1, 1 represents a liquid crystal panel as a display panel. A semiconductor device 4 is mounted at the middle of a longer side (periphery) of the rectangular liquid crystal panel 1.

The semiconductor device 4 includes, as also shown in FIG. 2, rectangular semiconductor elements 5 mounted thereto. The elements 5 primarily constitute liquid crystal drivers. Here, for illustrative purposes, three semiconductor elements 5 are mounted as an example. This is by no means intended to limit the number of semiconductor elements packaged in one semiconductor device in the present invention.

The semiconductor device 4 has one carrier tape 6 as a basic component. The carrier tape 6 is fabricated by forming a wiring layer on an insulating film base material. On the carrier tape 6, the multiple semiconductor elements 5 are packaged by COF whereby no device hole is made through the carrier tape 6.

The semiconductor device 4 is provided with output outer leads 2 for connecting to the liquid crystal panel 1 and input outer leads 3 for signal input to the semiconductor device 4. The semiconductor device 4 and the liquid crystal panel 1 are joined by the output outer leads 2.

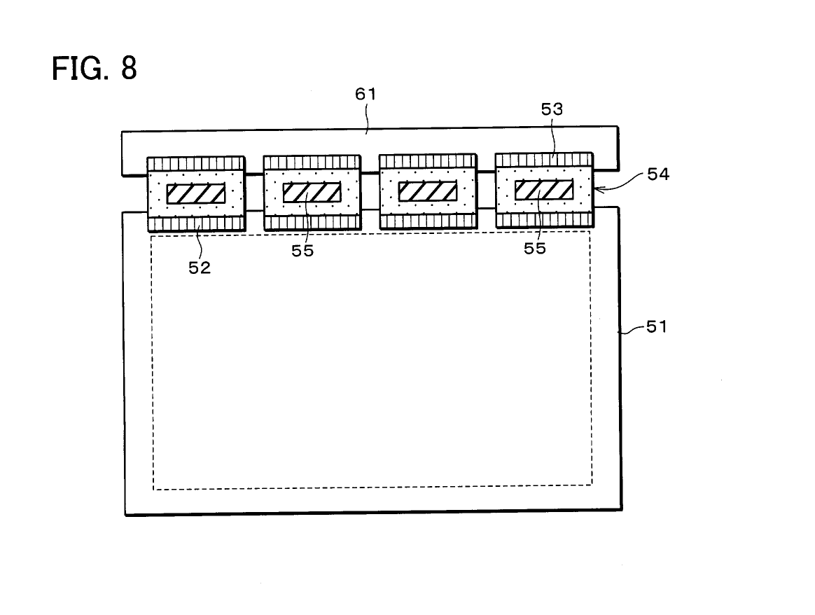

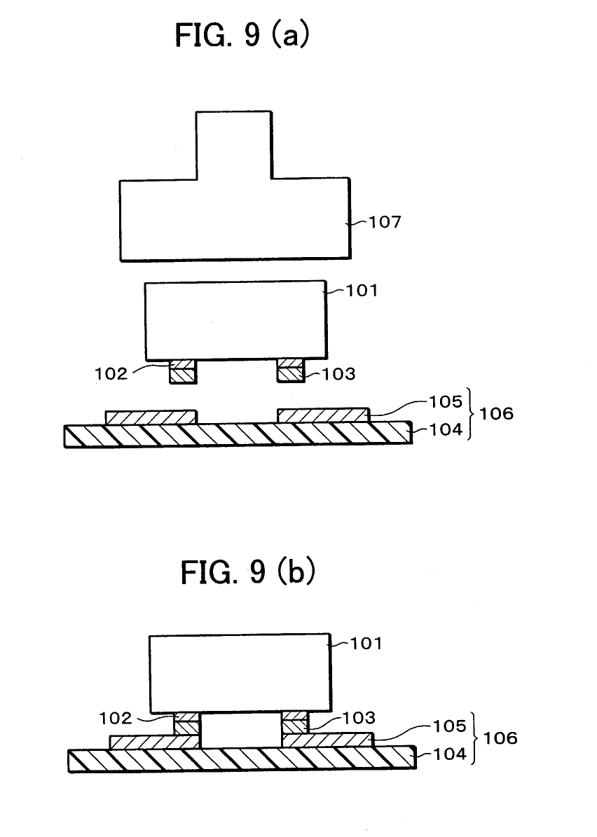

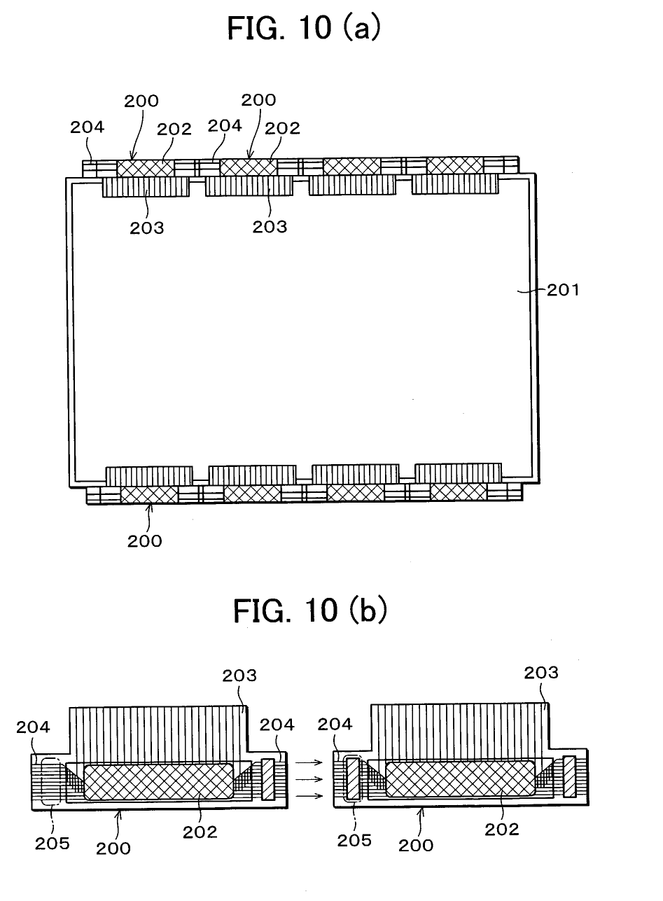

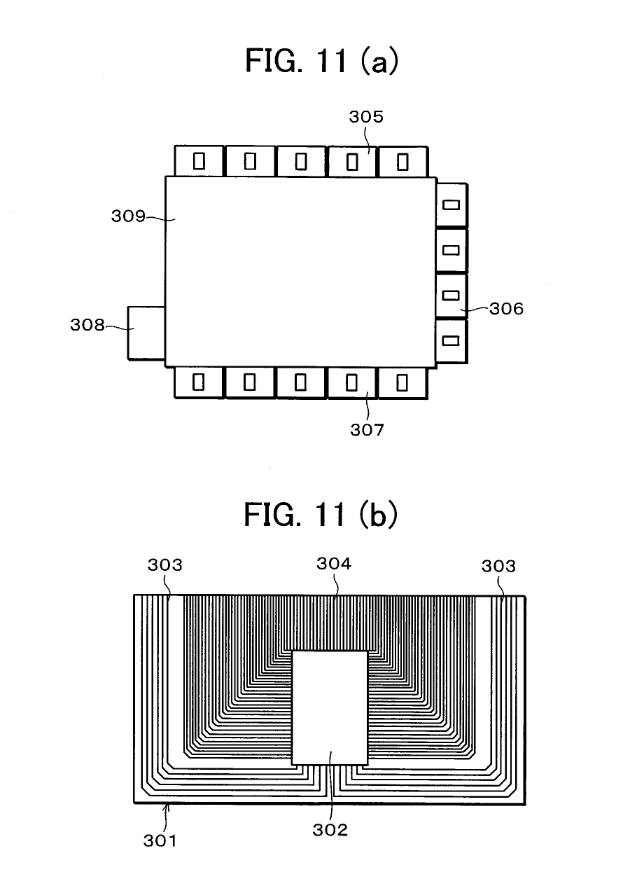

In packaging semiconductor elements 5 required to drive the liquid crystal panel 1 in the liquid crystal panel 1, in the conventional arrangement shown in FIG. 8, each semiconductor element 55 is mounted using an individual carrier tape to fabricated a semiconductor device 54, and the multiple semiconductor devices 54 are then placed and mounted to the periphery of the liquid crystal panel 51.

However, as in the foregoing, in the arrangement in accordance with the present invention, multiple semiconductor elements 5 required to drive the liquid crystal panel 1 are packaged together using one carrier tape 6 to fabricate one semiconductor device 4.

Thus, the wired boards 61 (see FIG. 8) can be omitted which is indispensable in the conventional arrangement and which connects the input side of the semiconductor devices 54 shown in FIG. 8. Cost is reduced, and the liquid crystal panel module can be reduced in size accordingly.

Besides, the number of expensive carrier tapes 6 can be reduced down to one. Cost is reduced accordingly. Besides, in a packaging step to connect the semiconductor device 4 to the liquid crystal panel 1, the use of only one semiconductor device 4 requires only one step to mount the device 4 to the liquid crystal panel 1. Cost is again reduced. In contrast, in the conventional arrangement, multiple semiconductor devices 54 need to be packaged, which requires multiple steps.

Further, mounting semiconductor elements 5 together on one carrier tape 6 enables the wiring distance for a common signal input to the semiconductor elements 5 to be reduced. This makes it possible to avoid occurrence of, for example, characteristics abnormalities (display abnormalities) caused by a voltage drop or like phenomena which is a defect caused by added length of the input signal wiring and greater need for high speed operation of the input signal.

In addition, the pitch between the output outer leads 2 of the semiconductor device 4 does not need to be changed even if the display panel 1 is resized while retaining the original pixel count of the display panel 1. The arrangement is therefore versatile.

In the semiconductor device 4, the semiconductor elements 5 are laid out so that their longitudinal directions are aligned with, and lined up along, the longitudinal direction of the rectangular carrier tape 6. That is, in the liquid crystal panel module of FIG. 1, the longitudinal and lined-up directions of the semiconductor elements 5 match the longitudinal direction of the carrier tape 6, and the longitudinal direction of the carrier tape 6 matches the longitudinal direction of the liquid crystal panel 1.

The semiconductor device 4 comes to acquire a narrow and long shape by, in packaging the semiconductor elements 5 using one carrier tape 6 together, aligning the longitudinal directions of the semiconductor elements 5 to the longitudinal direction of the carrier tape 6 and laying out the longitudinal directions of the semiconductor elements 5 parallel to the longitudinal direction of the carrier tape 6.

By making the semiconductor device 4 long and narrow, the frame on the side where the semiconductor device 4 is mounted to the liquid crystal panel module does not have an added width and can accommodate a desired narrow frame. Especially, here, the semiconductor elements 5 are laid out along a straight line, making the shape of the semiconductor device 4 longest and narrowest.

Besides, in the semiconductor device 4, the adjacent semiconductor elements 5 are separated by a distance W of about 1 mm. This is a value obtained by considering the precision of current ILB devices and the substance and heat expansion coefficient of the carrier tape 6. When the semiconductor elements 5 are lined up and packaged using the same carrier tape 6 in this manner, thermal stress in ILB, for example, can affect the dimensions of inner leads at a site where an adjacent semiconductor element is packaged. The applicant has confirmed that if the separation distance W falls below 1 mm, the inner lead dimensions of the wiring layer on the carrier tape 6 will highly likely vary, the semiconductor elements 5 not be connected to the inner lead in a good manner, and the semiconductor device 4 not function as desired. Specifying the separation distance W to 1 mm or more will avoid such defects from developing.

In such a semiconductor device 4, signals are fed to the mounted semiconductor elements 5 via the input outer leads 3. Some of the input signal, for example, a clock signal, horizontal synchronization signal, vertical synchronization signal, start pulse signal, and a power source need to be shared among the semiconductor elements 5. Each semiconductor element 5 produces a different output signal based on an input signal. The output signals from the semiconductor elements 5 are supplied to the liquid crystal panel 1 via the output outer leads 2.

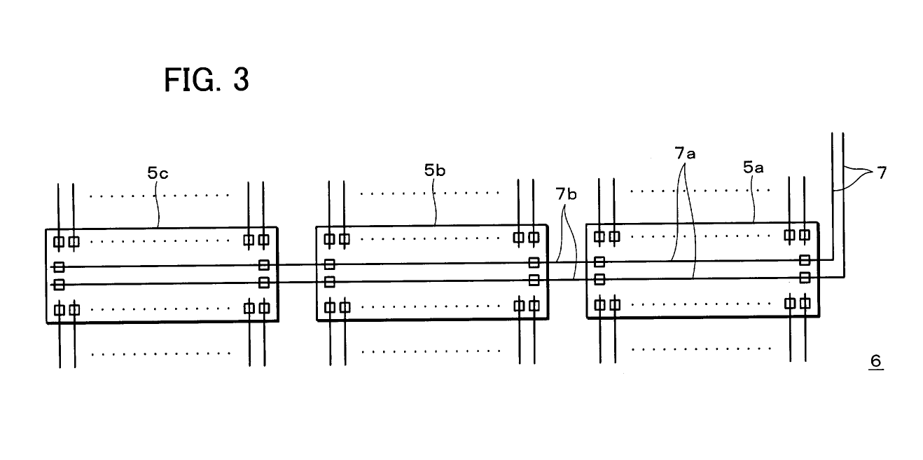

FIG. 3 shows a wiring state of the semiconductor device 4. As shown in FIG. 3, the semiconductor device 4 is provided with a signal transfer wires 7 which transfer input signals commonly to the mounted semiconductor elements 5. Of the input signals to the semiconductor device 4 via the input outer leads 3, the clock signal, the synchronization signal, the start pulse signal, and other input signals, as well as the power source, which need to be shared among the semiconductor elements 5 are transferred via the signal transfer wires 7.

The signals fed from the input outer leads 3 to the signal transfer wires 7 first enter the semiconductor element 5a and pass through the semiconductor element 5a before entering the adjacent semiconductor element 5b. The signals then pass through the semiconductor element 5b and enters the adjacent semiconductor element 5c. The signals are transferred sequentially through the semiconductor element 5a, the semiconductor element 5b, and the semiconductor element 5c.

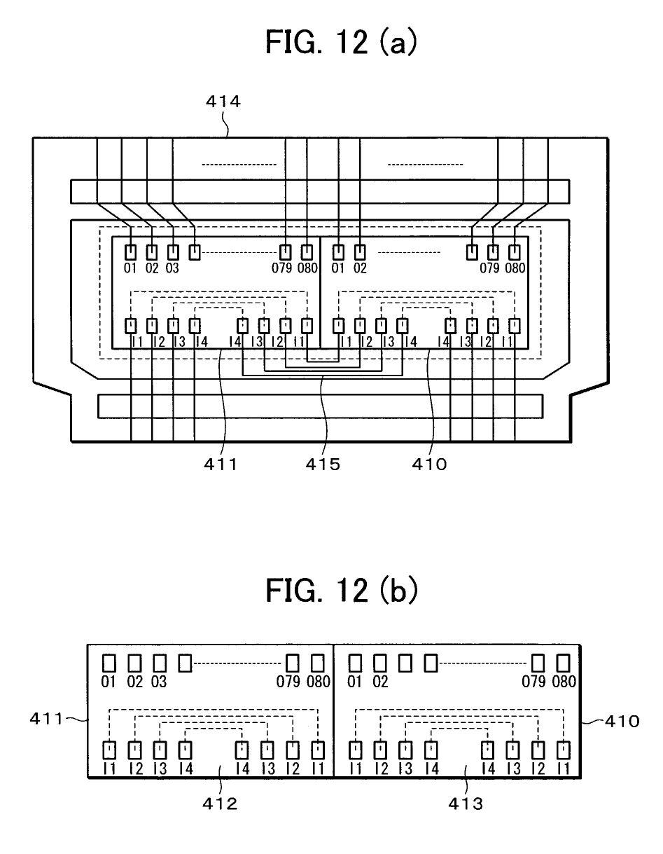

The signal transfer wires 7 include wires 7a extending through the semiconductor elements 5 and wires 7b running on the carrier tape 6 between the semiconductor elements 5. In conventional arrangement (see FIG. 12) in which multiple semiconductor elements are installed and interconnected side by side in a single device hole, the wires connecting the semiconductor elements are run in a square “U” shape due to the provision of the device hole. However, in this manner, the presence of the film base material of the carrier tape 6 between the adjacent semiconductor devices 5 and the interconnections between the adjacent semiconductor elements 5 via the wiring layer (part of the wires 7b) on the carrier tape 6 enables the connection lines to extend straightly and more effectively avoid defects due to elongated signal transfer wires 7.

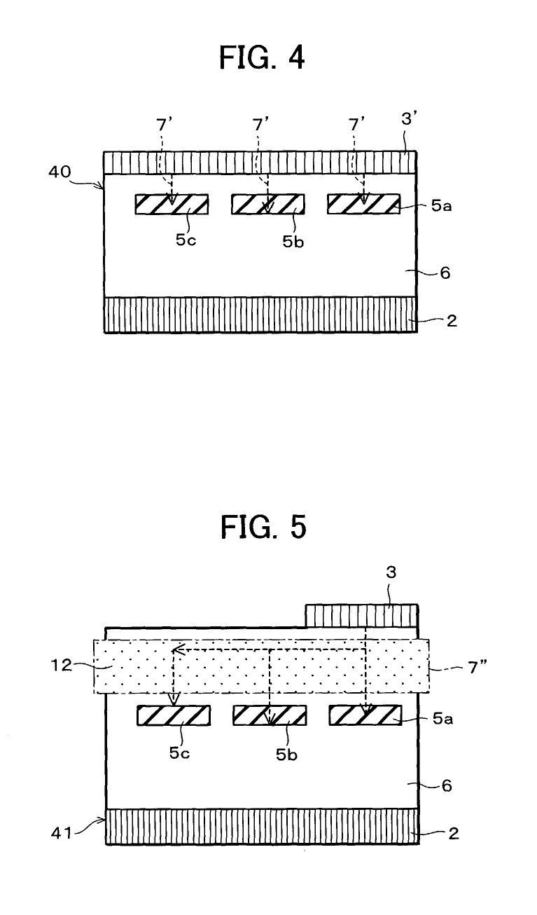

Here, FIG. 4 shows a plan view a semiconductor device 40 adapted to include mounted semiconductor elements 5 each having a different set of signal transfer wires 7′ connected to the input outer leads 3′ so that the common signals are fed through the signal transfer wires 7′. In the semiconductor device 40, the semiconductor elements 5 have respective sets of outer leads 3′ through which the signals shared commonly among the semiconductor elements 5 are fed. The input outer leads 3′ inevitably occupy increased areas; such a specification runs counter to cost cuts.

In contrast, in the semiconductor device 4 in FIG. 2, the input section for the common signals is reduced to that for a single semiconductor element; the input outer leads 3 occupies less areas. Less amounts of the film base material is used in the carrier tape 6, contributing to cost cuts.

FIG. 5 shows a plan view of a semiconductor device 41. The input outer leads 3 are collectively formed similarly to the present invention; however, signal transfer wires 7″ through which the common signals are fed to the semiconductor elements 5 are formed on the carrier tape 6. The arrangement of the semiconductor device 41 requires a space 12 to form the signal transfer wires 7″ on the carrier tape 6. The space 12 is shown in dots in the figure.

In contrast, in the semiconductor device 4 in FIG. 2, the signal transfer wires 7 are laid out through the semiconductor elements 5, requiring no space 12. Less amounts of the film base material is used in the carrier tape 6, contributing to cost cuts.

Further, the signal transfer wires 7 are laid out between the semiconductor elements 5, taking the straight, hence shortest, paths. This enables the input signal to be adapted for increased speed and reduces undesirable characteristics and other defects caused by a voltage drop which in turn is caused by increased wire lengths.

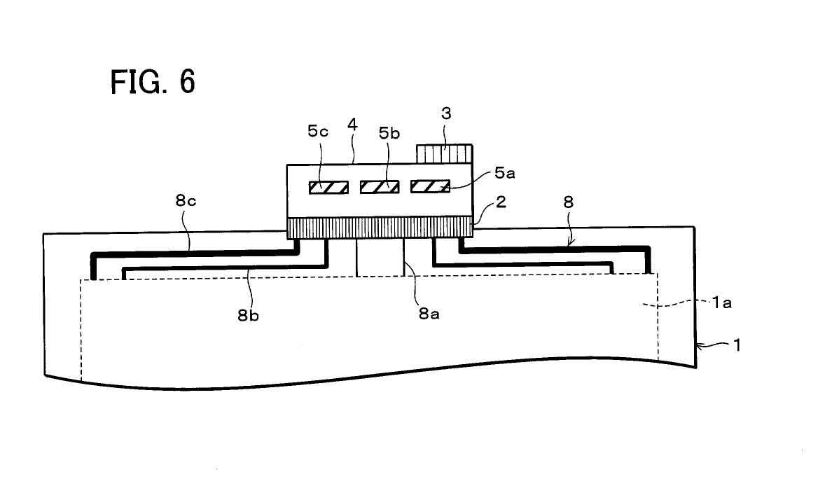

Next, referring to FIG. 6, features will be described of the wiring on the liquid crystal panel 1 to which such a semiconductor device 4 is mounted.

As shown in FIG. 6, the semiconductor device 4 is placed at the middle of the periphery of the rectangular liquid crystal panel 1. Here, the output signal from the semiconductor device 4 is output through the output outer leads 2 and transferred to the signal lines of the liquid crystal panel 1 through the on-board wiring (connecting wires) 8 on the glass board 1a constituting the liquid crystal panel 1.

Here, the on-board wiring 8 is divided into three regions, 8a, 8b, and 8c, according to the separation distance between the output outer leads 2 and the input terminals for the signal lines of the liquid crystal panel 1: 8a is the closest to the output outer leads 2 of the semiconductor device 4; 8c, the farthest; and 8b, between these two.

The resistance value of the on-board wiring 8 grows with an increasing connecting distance between the input terminals (not shown) of the liquid crystal panel 1 and the output outer leads 2 of the semiconductor device 4. Therefore, the on-board wiring 8 has the greatest wire width in the region 8c which is the farthest from the output outer leads 2 of the semiconductor device 4, and narrows down in the region 8b which is somewhat closer to the output outer leads 2 of the semiconductor device 4, and further down in the region 8c which is the closest to the output outer leads 2 of the semiconductor device 4.

By causing the wire width to differ in this manner, the voltage drop caused by an added wiring distance of the on-board wiring 8 can be alleviated, and it becomes possible to supply the same voltage regardless of wiring distance.

Besides, in the present embodiment the semiconductor device 4 is mounted at the middle of the periphery of the liquid crystal panel 1 (the middle of a side of the liquid crystal panel 1 on which the semiconductor device 4 is placed). This gives the following advantages.

The number of outputs from the output outer leads 2 of the semiconductor device 4 is dictated by the resolution of the liquid crystal panel 1. The currently popular resolution for a large-scale liquid crystal panel 1 is VGA, or 640×480 pixels. Actually, to produce a color display, RGB outputs, i.e., 640×3=1920 outputs, are necessary. As the on-board wiring 8, 1920 wires need to be formed on the glass board 1a.

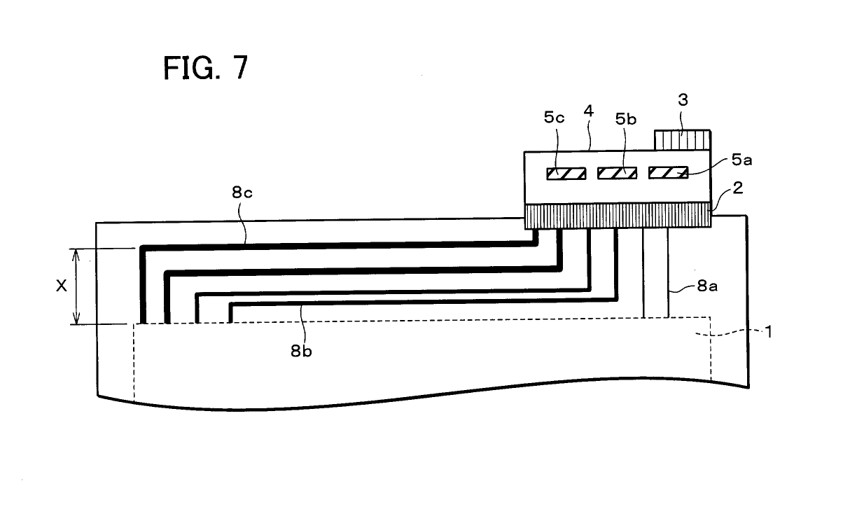

Here, if as in FIG. 7, the semiconductor device 4 is mounted at an end of the liquid crystal panel 1 (an end of the side of the liquid crystal panel 1 on which the semiconductor device 4 is placed), a space with a width X of about 40 mm is needed as the region in which the on-board wiring 8 is formed, provided that the on-board wiring 8 has an L/S (wire width/interval (space) between adjacent wires) of about 10 μm/10 μm.

In contrast, if the semiconductor device 4 is mounted at the middle of a long side of the liquid crystal panel 1 as in FIG. 6, the aforementioned space, i.e., the width X, would be sufficient if it is about half the foregoing value. in the future, with the progressively higher resolution liquid crystal panel, such as XGA, SVGA, the number of the on-board wiring 8 increases and requires a larger region to form them. As shown in FIG. 6, the arrangement is effective where the semiconductor device 4 is placed at the middle of the liquid crystal panel 1.

Besides, as another scheme to prevent a voltage drop caused by an increased wiring distance of the on-board wiring 8, the wires in the on-board wiring 8 may be changed in thickness in accordance with the separation distance between the outer leads 2 and the input terminals of the signal lines of the liquid crystal panel 1, rather than changing the on-board wiring 8 in width from region to region.

That is, the on-board wiring 8 is made increasingly thick with increasing distance between the input terminals of the liquid crystal panel 1 and the output outer leads 2 of the semiconductor device 4, so as to reduce resistance, prevent a voltage drop due to wiring distance, and avoid improper characteristics and other defects.

A method of changing the thickness of the on-board wiring 8 is, for example, to change the amounts of etching in the formation of the wires.

The on-board wiring 8 can be made to have a uniform resistance value irrespective of wiring distance through, for example, changing the wire width or changing the wire thickness. A comparison of these two methods in view of reduction in size of the display panel module size shows that the latter is preferable, because the former would require a wider region to form the on-board wiring 8 to accommodate the added width of the on-board wiring 8. The latter method, whereby the wire thickness is changed, does not expand the region to form the on-board wiring 8.

However, if the wire thickness is to be changed, an etching mask and additional manufacturing steps are required. The arrangement to change the wire width is desirable in terms of cost. The selection as to whether to change the width or thickness of the on-board wiring 8 may be made depending on the specifications of the liquid crystal panel module.

The on-board wiring 8 may be an ITO or other transparent conductive film. Since the wiring 8 does not contribute to display, it is preferably made of a less resistive material, such as copper or aluminum.

Further, the on-board wiring 8 is preferably provided with a protection film of polyimide or anther substance covering the wiring 8, so as to reduce oxidation and short-circuiting of the wiring 8.

A semiconductor device in accordance with the present invention, as in the foregoing, is a semiconductor device including multiple semiconductor elements packaged using one carrier tape having a wiring layer formed on an insulating film base material, and characterized by

the semiconductor elements being substantially rectangular and laid out so that longitudinal directions thereof are aligned with, and lined up along, a longitudinal direction of the substantially rectangular carrier tape,

the film base material existing between adjacent semiconductor elements, and

the wiring layer formed on the film base material interconnecting the adjacent semiconductor elements.

First, this mounts multiple semiconductor elements together on a single carrier tape. The following functions are enabled.

The number of expensive carrier tapes is reduced, and so is the cost. A single packaging step is capable of connecting the semiconductor device to the display panel; the number of steps is reduced, and so is the cost.

Unlike those cases when semiconductor devices in which semiconductor elements are individually packaged are mounted, there is no need for a wired board linking the semiconductor devices. The device therefore enables cost reduction and allows for downsizing of the display panel module.

The length of the input signal wiring can be reduced, in comparison to those cases when semiconductor devices in which semiconductor elements are individually packaged are mounted. This makes it possible to avoid occurrence of, for example, characteristics abnormalities (display abnormalities) caused by a voltage drop or like phenomena which is a defect caused by added length of the input signal wiring and greater need for high speed operation of the input signal.

The pitch between the outer leads of the semiconductor device does not need to be changed even if the display panel is resized while retaining the original pixel count of the display panel. Good versatility is obtained.

Next, with the arrangement, the semiconductor elements are substantially rectangular and laid out so that the longitudinal directions thereof are aligned with, and lined up along, the longitudinal direction of the substantially rectangular carrier tape. This enables the semiconductor device to have a long and narrow shape. By making the semiconductor device in a long and narrow shape, when a display panel module is arranged by mounting a semiconductor device to the periphery of a display panel, those situations can be effectively avoided in which the frame of the module on the side to which the semiconductor device is mounted becomes too wide.

In addition, with the arrangement, the film base material exists between the adjacent semiconductor elements, and the wiring layer formed on the film base material interconnects the adjacent semiconductor elements. Therefore, the input signal wiring distance can be made short (the elements can be interconnected through straight paths), in comparison to the arrangement (iii) of the aforementioned conventional technique, that is, the arrangement in which the wires are drawn outside the device hole and run in a square “U” shape. Defects are more effectively avoided which are caused by added length of the input signal wiring.

As a result, a semiconductor device can be provided which enables reduction in size and cost of the liquid crystal panel module, while reducing characteristics abnormalities which occur due to added wiring distance for input signals and avoiding losses in signal transfer speed.

Besides, the semiconductor device in accordance with the present invention is preferably arranged so as to be of a COF type where the carrier tape does not have a hole in which the semiconductor elements are mounted.

The semiconductor device packaging may be performed by either COF where the carrier tape is not provided with a hole in which the semiconductor elements are mounted (hereinafter, a device hole) or TCP where such a device hole is provided. In TCP, a device hole may be formed for each semiconductor element. However, when a device hole is formed for each semiconductor element, the intervals between the adjacent semiconductor elements are inevitably long when compared to cases where the elements are packaged by COF using no device holes. This runs counter to downsizing of the semiconductor device. Therefore, it is preferable for the present invention to employ COF in packaging the semiconductor elements.

Besides, the semiconductor device in accordance with the present invention is preferably arranged so that the semiconductor elements are laid out in a in a straight line.

Laying out the semiconductor elements in a straight line enables the width of the semiconductor device to be small, provided that the dimensions of the mounted semiconductor elements remains unchanged. As a result, the frame of the display panel module on the side to which the semiconductor device is mounted can be more effectively narrowed down.

Besides, the semiconductor device in accordance with the present invention is preferably arranged further so that wires interconnecting the adjacent semiconductor elements propagate input signals and operational power.

The semiconductor elements constituting a driver for driving the display panel need to share a clock signal, a horizontal synchronization signal, a vertical synchronization signal, a start pulse signal, and other input signals, as well as power source. Therefore, causing the input signals and operational power to propagate through the wires interconnecting the adjacent semiconductor elements in this manner enables the input signals and operational power to be transferred without developing defects caused by added wiring distance.

As in the foregoing the display panel module in accordance with the present invention is characterized in that the semiconductor device in accordance with the present invention is mounted to the periphery of a display panel as a drive circuit for driving the display panel.

As mentioned earlier, the semiconductor device in accordance with the present invention is a semiconductor device which enables reduction in size and cost of the liquid crystal panel module, while reducing characteristics abnormalities which occur due to added wiring distance for input signals and avoiding losses in signal transfer speed.

Therefore, the display panel module in accordance with the present invention in which such a semiconductor device is mounted enables reduction in size and cost, while reducing characteristics abnormalities which occur due to added wiring distance for input signals and avoiding losses in signal transfer speed.

Besides, the display panel module in accordance with the present invention is preferably arranged so that the semiconductor device is placed in the middle of a display region which the semiconductor device is responsible for driving.

When the semiconductor device is mounted to the display panel, the input terminals of the display panel are connected to the output sections (output outer leads, or a part of the wiring layer) of the semiconductor device; if these connecting wires have an identical thickness and width, the greater the wiring distance, the higher the wire resistance value. Besides, if straight paths cannot be found from the output sections of the semiconductor device to the input terminals of the display panel, the connecting wires are run in the direction along a side face of the display panel on which the semiconductor device is mounted; therefore, the more the connecting wires, the greater the region in which the connecting wires are provided on the board constituting the display panel.

Accordingly, in the arrangement, the semiconductor device is placed in the middle of a display region which the semiconductor device is responsible for driving. Thus, the connecting wires are provided partly on the left hand side and partly on the right hand side, and therefore shorter than provided on an end of the display panel. Besides, the number of wires running in the direction along a side face of the display panel is halved approximately, and therefore the region in which the connecting wires are provided on the board, allowing for downsizing of the display panel module size.

Besides, the display panel module in accordance with the present invention may be arranged so that wires formed on the display panel, connecting the output sections of the semiconductor device to the input terminals of the multiple signal lines which are formed on the display panel and driven by the semiconductor device, have a width which changes according to the wiring distance from the output sections of the semiconductor device to the input terminals of the display panel.

As mentioned earlier, when the semiconductor device is mounted to the display panel, the input terminals of the display panel are connected to the output sections of the semiconductor device; if these connecting wires have an identical thickness and width, the greater the wiring distance, the higher the wire resistance value. Therefore, changing the width of the connecting wires appropriately according to the wiring distance from the output sections of the semiconductor device to the input terminals of the display panel in this manner eliminates the difference in the resistance value between the connecting wires and makes the signal transfer characteristics uniform between the connecting wires. In other words, appropriately, the connecting wires has a width which increases with the wiring distance from the output terminals of the semiconductor device to the input terminals of the display panel.

Besides, the display panel module in accordance with the present invention may be arranged so that wires formed on the display panel, connecting the output sections of the semiconductor device to the input terminals of the multiple signal lines which are formed on the display panel and driven by the semiconductor device, have a thickness which changes according to the wiring distance from the output sections of the semiconductor device to the input terminals of the display panel.

As mentioned earlier, when the semiconductor device is mounted to the display panel, the input terminals of the display panel are connected to the output sections of the semiconductor device; if these connecting wires have an identical thickness and width, the greater the wiring distance, the greater the wire resistance value. Therefore, changing the thickness of the connecting wires appropriately according to the wiring distance from the output sections of the semiconductor device to the input terminals of the display panel in this manner eliminates the difference in the resistance value between the connecting wires and makes the signal transfer characteristics uniform between the connecting wires. In other words, appropriately, the connecting wires has a thickness which increases with the wiring distance from the output sections of the semiconductor device to the input terminals of the display panel.

Besides, the semiconductor device and display panel module in accordance with the present invention may be depicted as in the following:

A semiconductor device in accordance with the present invention is a semiconductor device of a COF type including wires formed on a film substrate (film base material) and a packaged liquid crystal driver which is semiconductor elements for driving a liquid crystal panel, and arranged so that rectangular semiconductor elements primarily constituting a liquid crystal driver are packaged parallel to a long side of the semiconductor device using a film substrate (COF).

Besides, a display panel module in accordance with the present invention is a semiconductor device in which a liquid crystal driver which is semiconductor elements for driving a liquid crystal panel is packaged, and arranged to include three or more rectangular semiconductor elements primarily constituting a liquid crystal driver packaged using one film substrate (COF) on which wires are formed parallel to a long side of the liquid crystal panel.

Besides, a semiconductor device in accordance with the present invention is further arranged so that three or more semiconductor elements are formed on one substrate (COF) in a straight line laid out.

Besides, a semiconductor device in accordance with the present invention is further arranged so that input signals and operational power for the semiconductor elements are transferred through the adjacent semiconductor elements and that the wires are embodied by signal and power source lines formed on the substrate.

A display panel module in accordance with the present invention is a liquid crystal panel module including the aforementioned semiconductor device in accordance with the present invention connected and mounted to the liquid crystal panel, and arranged so that the semiconductor device in which a liquid crystal driver which is semiconductor elements for driving a liquid crystal panel is packaged and that three or more rectangular semiconductor elements primarily constituting a liquid crystal driver are packaged using one film substrate (COF) on which wires are formed parallel to a long side of the liquid crystal panel.

Besides, a display panel module in accordance with the present invention may be further arranged only one semiconductor device is provided at a middle of a periphery of the liquid crystal panel.

Besides, a display panel module in accordance with the present invention may be further arranged so that wires formed on a glass board providing connections between the semiconductor device and the liquid crystal panel have a width which changes according to the distance from the semiconductor device to the input terminals of the liquid crystal panel.

Besides, a display panel module in accordance with the present invention may be further arranged so that the greater the distance from the semiconductor device to the input terminals of the liquid crystal panel, the greater the width of the wires formed on the glass board.

Besides, a display panel module in accordance with the present invention may be further arranged so that wires formed on a glass board providing connections between the semiconductor device of the liquid crystal panel module and the liquid crystal panel have a thickness which changes according to the distance from the semiconductor device to the input terminals of the liquid crystal panel.

Besides, a display panel module in accordance with the present invention may be further arranged so that the greater the distance from the semiconductor device to the input terminals of the liquid crystal panel, the greater the thickness of the wires formed on the glass board.

As in the foregoing, three or more rectangular semiconductor elements primarily constituting a liquid crystal driver are mounted parallel to a long side of the liquid crystal panel using one semiconductor device (COF). This reduces the input signal wiring distance and allows for increased signal transfer speed.

Besides, the inclusion of only one semiconductor device and the elimination of the need for the film substrate linking multiple semiconductor devices (a conventional, large-scale liquid crystal panel uses multiple semiconductor devices) enables cost cuts and downsizing of the liquid crystal panel module.

Further, changing the width and thickness of the wires on a glass board provided to transfer output signals from the semiconductor device to the liquid crystal panel according to the connecting distance from the output terminals of the semiconductor device to the input terminals of the liquid crystal panel enables alleviation of voltage drop and like phenomena caused by the distance.

The invention being thus described, it will be obvious that the same way may be varied in many ways. Such variations are not to be regarded as a departure from the spirit and scope of the invention, and all such modifications as would be obvious to one skilled in the art are intended to be included within the scope of the following claims.

What is claimed is:

1. A semiconductor device, including multiple semiconductor elements packaged using one carrier tape including an insulating film base material and a wiring layer formed thereon,
the semiconductor elements being substantially rectangular and laid out so that longitudinal directions thereof are aligned with, and lined up along, a longitudinal direction of the substantially rectangular carrier tape,
the film base material existing between adjacent semiconductor elements, and
the wiring layer formed on the film base material interconnecting the adjacent semiconductor elements.

2. The semiconductor device as set forth in claim 1, wherein
the semiconductor device is of a COF type where the carrier tape does not have a hole in which the semiconductor elements are mounted.

3. The semiconductor device as set forth in claim 1, wherein
the semiconductor elements are laid out in a straight line.

4. The semiconductor device as set forth in claim 1, wherein
wires interconnecting the adjacent semiconductor elements propagate input signals and operational power.

5. The semiconductor device as set forth in claim 4, wherein
the input signals include a clock signal, a synchronization signal, and a start pulse signal.

6. A display panel module, including a semiconductor device mounted to a periphery of a display panel as a drive circuit for driving the display panel,
the semiconductor device having multiple semiconductor elements packaged using one carrier tape including an insulating film base material and a wiring layer formed thereon,
the semiconductor elements in the semiconductor device being substantially rectangular and laid out so that longitudinal directions thereof are aligned with, and lined up along, a longitudinal direction of the substantially rectangular carrier tape,
the film base material existing between adjacent semiconductor elements, and
the wiring layer formed on the film base material interconnecting the adjacent semiconductor elements.

7. The display panel module as set forth in claim 6, wherein
wires formed on the display panel, connecting output sections of the semiconductor device to input terminals of multiple signal lines which are formed on the display panel and driven by the semiconductor device, have a width which changes according to a wiring distance from the output sections of the semiconductor device to the input terminals of the display panel.

8. The display panel module as set forth in claim 7, wherein
the longer the wiring distance from the output sections to the input terminals, the greater the width of the wires connecting the output sections of the semiconductor device to the input terminals of the display panel.

9. The display panel module as set forth in claim 6, wherein
wires formed on the display panel, connecting output sections of the semiconductor device to input terminals of multiple signal lines which are formed on the display panel and driven by the semiconductor device, have a thickness which changes according to a wiring distance from the output sections of the semiconductor device to the input terminals of the display panel.

10. The display panel module as set forth in claim 9, wherein
the longer the wiring distance from the output sections to the input terminals, the greater the thickness of the wires connecting the output sections of the semiconductor device to the input terminals of the display panel.

11. A display panel module, including a semiconductor device mounted to a periphery of a display panel as a drive circuit for driving the display panel,
the semiconductor device having multiple semiconductor elements packaged using one carrier tape including an insulating film base material and a wiring layer formed thereon,
the semiconductor device being placed in a middle of a display region which the semiconductor device is responsible for driving,
the semiconductor elements in the semiconductor device being substantially rectangular and laid out so that longitudinal directions thereof are aligned with, and lined up along, a longitudinal direction of the substantially rectangular carrier tape,
the film base material existing between adjacent semiconductor elements, and
the wiring layer formed on the film base material interconnecting the adjacent semiconductor elements.

12. The display panel module as set forth in claim 11, wherein
wires formed on the display panel, connecting output sections of the semiconductor device to input terminals of multiple signal lines which are formed on the display panel and driven by the semiconductor device, have a width which changes according to a wiring distance from the output sections of the semiconductor device to the input terminals of the display panel.

13. The display panel module as set forth in claim 12, wherein
the longer the wiring distance from the output sections to the input terminals, the greater the width of the wires connecting the output sections of the semiconductor device to the input terminals of the display panel.

14. The display panel module as set forth in claim 11, wherein
wires formed on the display panel, connecting output sections of the semiconductor device to input terminals of multiple signal lines which are formed on the display panel and driven by the semiconductor device, have a thickness which changes according to a wiring distance from the output sections of the semiconductor device to the input terminals of the display panel.

15. The display panel module as set forth in claim 14, wherein
the longer the wiring distance from the output sections to the input terminals, the greater the thickness of the wires connecting the output sections of the semiconductor device to the input terminals of the display panel.
